(19) United States
(12) Patent Application Publication
(10) Pub. No.: US 2026/0043856 A1
(43) Pub. Date: Feb. 12, 2026

(54) BATTERY PACK CONTACT BREAK DETECTION

(71) Applicant: Caterpillar Inc., Peoria, IL (US)

(72) Inventors: Mahadevan Unnikrishnan, Bangalore (IN); Bharath Balakrishnan, Bangalore (IN); Murali Krishnan Raghupathy, Bangalore (IN); Stephen A. Edwards, Peterborough (GB)

(21) Appl. No.: 18/751,648

(22) Filed: Jun. 24, 2024

(51) Int. Cl. G01R 31/3835

(52) U.S. Cl. CPC G01R 31/3835

(57) ABSTRACT

The present technology is directed to methods and systems for detecting a contact break in a battery pack. In some embodiments, the method includes, for example, (i) receiving information regarding a current voltage value of a battery pack; (ii) providing information regarding a mean voltage value of the battery pack; (iii) determining a calculated value based on the current voltage value of the battery pack and the mean voltage value of the battery pack; and (iv) identifying a contact break of the battery pack based on the calculated value.

### TECHNICAL FIELD

The present application is related to systems and methods for detecting a contact break in a battery pack. More particularly, the present methods utilize moving average and normalization schemes to detect voltage changes of battery packs. The battery packs can be used in various systems such as industrial machines, vehicles, and devices.

### BACKGROUND

Battery packs are commonly used in various industries. In a battery pack, there can be multiple cells connected in parallel by a welded busbar. A contact break in this connection (e.g., due to a poor weld, vibrations, manufacturing defects, etc.) can lead to overheating and thus raise safety concerns. Traditional approaches include measuring voltages changes of a battery. However, without cell-level monitoring or measurement, it is difficult to detect the foregoing contact break. For example, U.S. Patent Publication No. 2022/1790089 (Lee) discloses a method for diagnosing a battery bank by monitoring voltage changes of the battery bank. Lee's methods do not provide cell-level monitoring and thus are not sufficient to detect contact breaks within battery packs. Therefore, it is advantageous to have an improved method and system to address the foregoing needs.

### SUMMARY

The present technology is directed to methods and systems for detecting a contact break in a battery pack. In some embodiments, the battery pack can have cells connected in parallel within a module (e.g., a welded busbar). The contact break in such connection can happen due to a poor weld, machine vibrations or other manufacturing defects. When a cell of the battery pack does not function properly (e.g., a cell break), a current/voltage imbalance can also happen. The contact break and the imbalance can lead to safety concerns such as overheating. The present technology enables an operator to effectively and timely detect the foregoing contact breaks, imbalances, and defects. In some embodiments, the method includes, for example, (i) receiving, by a measurement module of the system, information regarding a current voltage value of a battery pack; (ii) providing, by a data storage module of the system, information regarding a mean voltage value of the battery pack; (iii) determining, by a calculation module of the system, a calculated value based on the current voltage value of the battery pack and the mean voltage value of the battery pack; and (iv) identifying, by a verification module of the system, a contact break of the battery pack based on the calculated value.

In some embodiments, the present technology can be implemented in a system with a controller and a memory. In various embodiments, the controller can be used to control a machine, a device, a vehicle, etc. In such embodiments, the controller are configured to: (1) receive, by a measurement module of the controller, information regarding a current voltage value of a battery pack; (2) provide, by a data storage module of the controller, information regarding a mean voltage value of the battery pack; (3) determine, by a calculation module of the controller, a calculated value based on the current voltage value of the battery pack and the mean voltage value of the battery pack; and (4) identify, by a verification module of the controller, a contact break of the battery pack based on the calculated value.

In some embodiments, the present technology can be implemented in a computing system with a processor and a memory. In such embodiments, the system can include at least one hardware processor and at least one non-transitory memory. The at least one non-transitory memory stores instructions, which, when executed by the at least one hardware processor, cause the system to: (A) receive information regarding a current voltage value of a battery pack; (B) provide, by a data storage module of the system, information regarding a mean voltage value of the battery pack; (C) determine, by a calculation module of the system, a calculated value based on the current voltage value of the battery pack and the mean voltage value of the battery pack; and (D) identify, by a verification module of the system, a contact break of the battery pack based on the calculated value.

### BRIEF DESCRIPTION OF THE DRAWINGS

FIG. 1 is a schematic diagram illustrating a detection system in accordance with embodiments of the present technology.

FIG. 2 is a schematic diagram illustrating a detection scheme in accordance with embodiments of the present technology.

FIG. 3 is a schematic diagram illustrating another detection scheme in accordance with embodiments of the present technology.

FIGS. 4A-4C are a schematic diagrams illustrating other detection schemes in accordance with embodiments of the present technology.

FIG. 5 is a schematic diagram illustrating operations of a detection system in accordance with embodiments of the present technology.

FIG. 6 is a schematic diagram illustrating components in a computing device in accordance with embodiments of the present technology.

FIG. 7 is a flow diagram showing a method in accordance with embodiments of the present technology.

### DETAILED DESCRIPTION

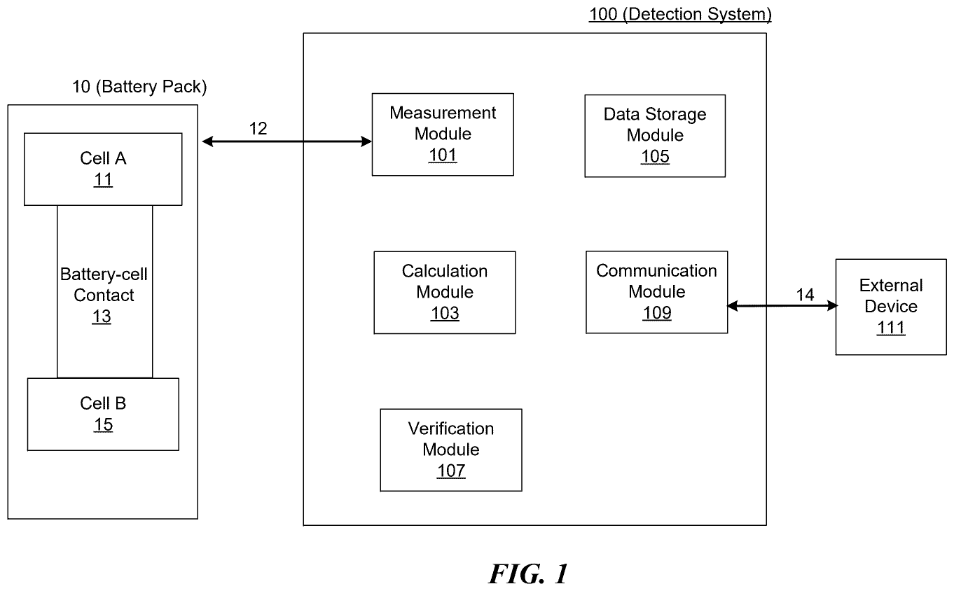

FIG. 1 is a schematic diagram illustrating a detection system 100 in accordance with embodiments of the present technology. The detection system 100 is configured to monitor and report a status of a battery pack 10. In some embodiments, the status can include a voltage value of the battery pack, a calculated value according on the voltage value, etc. In some embodiments, the status can include whether the battery pack 10 is functioning properly. For example, the detection system 100 can detect whether there is a contact break in the battery pack 10 based on the monitored status of the battery pack 10.

In the illustrated embodiments of FIG. 1, the battery pack 10 includes at least two battery cells (only Cell-A 11 and Cell-B 15 are shown in FIG. 1). The at least two battery cells are connected by the battery-cell contact 13. In some embodiments, the detection system 100 is configured to monitor the status of the battery pack 10 by monitoring a calculated value according on a measured current voltage value of the battery pack 10. In some embodiments, the status can include whether the battery pack 10 is functioning properly. For example, the detection system 100 can detect whether there is a contact break in the battery pack 10 based on the monitored status of the battery pack 10.

In some embodiments, the calculated value can include a difference between the current voltage value (noted as “V”) of the battery pack 10 and an average or a mean voltage value (e.g., in the past 24 hours or a longer time, noted as “MV”) of the battery pack 10. In some embodiment, for example, the value “MV” can be the average or the mean of all the cell voltages in a battery pack. In some embodiments, the value “V” can be an individual cell pair voltage (i.e., the voltage of a parallel-connected cell pair). The difference between the current voltage value V and the mean voltage value can be noted as “(V-MV),” as shown in Equation A below. In some embodiments, the calculated value can include a rate of change of the current voltage value V of the battery pack 10. The rate of change of the current voltage value V can be noted as “(dV/dt),” as shown in Equation B below. In some embodiments, the calculated value can include a rate of change of the mean voltage value MV of the battery pack 10. The rate of change of the mean voltage value V can be noted as “(dMV/dt),” as shown in Equation C below.

$$Voltage Difference = ( V - MV ) \qquad Equation A$$

$$Rate of Voltage Change = ( dV / dt ) \qquad Equation B$$

$$Rate of Mean Voltage Change = ( dMV / dt ) \qquad Equation C$$

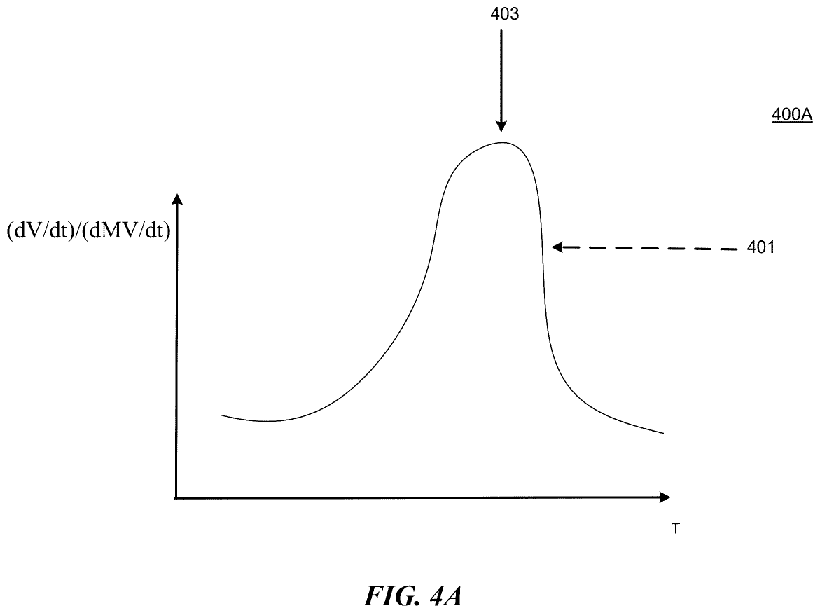

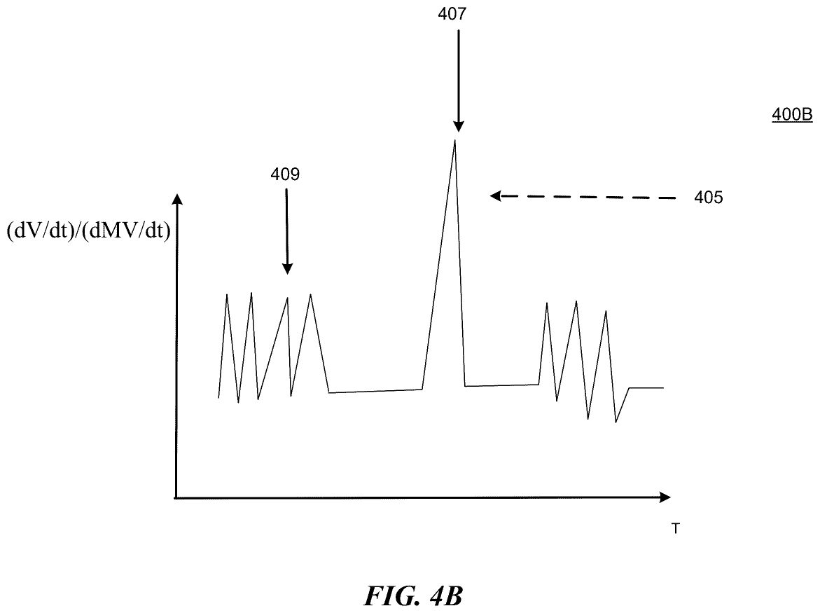

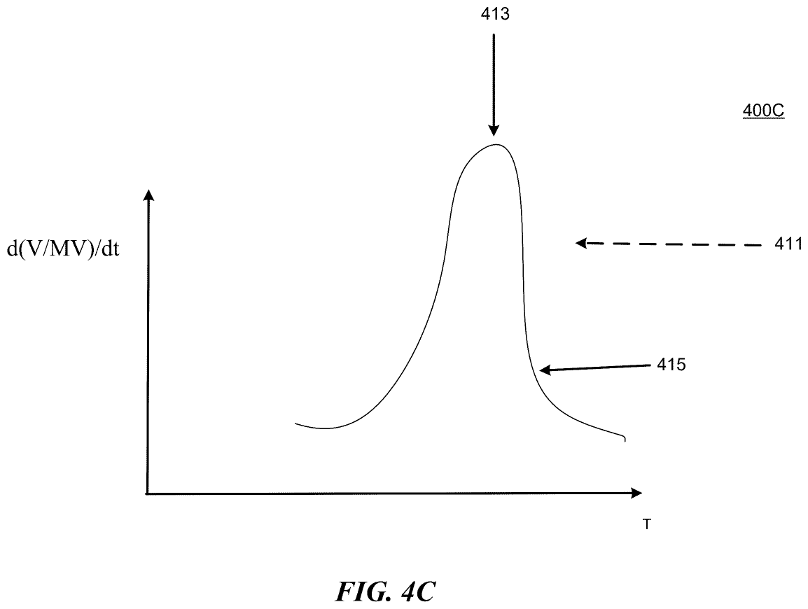

In some embodiments, the calculated value can include a first rate of change of the individual cell pair voltage value V of the battery pack 10 and a second rate of change of the mean voltage value MV of the battery pack 10. The first rate can be noted as “(dV/dt),” whereas the second rate can be noted as “(dMV/dt).” The first and second rates can be further used to calculate a ratio (e.g., dividing the first rate by the second rate, or vice versa), which can be used to monitor the tatus of the battery pack 10. In some embodiments, the ratio can be noted as “(dV/dt)/(dMV/dt),” as shown in Equation D1 below. Embodiments of the foregoing ratio are discussed in detail with reference to FIGS. 4A and 4B.

$$Voltage Ratio [ 1 ] = ( dV / dt ) / ( dMV / dt ) \qquad Equation D1$$

In some embodiments, the voltage ratio can be shown in a different form. For example, the voltage ratio can be a change along time of the value “V/MV,” as shown in Equation D2 below. Embodiments of the foregoing ratio are discussed in detail with reference to FIG. 4C.

$$Voltage Ratio [ 2 ] = d ( V / MV ) / dt ) \qquad Equation D2$$

In some embodiments, the calculated value can be generated based on a combination of multiple parameters such as the difference between the current voltage value and the mean voltage value “(V-MV),” the rate of change of the current voltage value “(dV/dt),” and the rate of change of the mean voltage value “(dMV/dt),” as shown in Equation E below.

$$Combination = ( V - MV ) + ( dV / dt ) + ( dMV / dt ) \qquad Equation E$$

In some embodiments, the combination can be a sum of the difference between the current voltage value and the mean voltage value “(V-MV)” and a ratio of the foregoing first and second rates “(dV/dt)/(dMV/dt).” The sum can be noted as “(V-MV)+(dV/dt)/(dMV/dt),” as shown in Equation F below.

$$Sum = ( V - MV ) + ( dV / dt ) / ( dMV / dt ) \qquad Equation F$$

As shown in FIG. 1, the detection system 100 includes a measurement module 101, a calculation module 103, a data storage module 105, a verification module 107, and a communication module 109. The measurement module 101 is configured to measure the current voltage value V of the battery pack 10 via a connection 12. The calculation module 103 is configured to calculate the calculated value as described above. For example, the calculated value can include (i) the difference between the current voltage value V (e.g., an individual cell pair voltage value) and the mean voltage value “(V-MV),” and/or the ratio of the current voltage value V and the mean voltage value “(V/MV),” (ii) the rate of change of the current voltage value “(dV/dt),” (iii) the rate of change of the mean voltage value MV of the battery pack “(dMV/dt),” (iv) the ratio of the foregoing rates “(dV/dt)/(dMV/dt),” any other suitable values based on the current voltage value V, a combination of the foregoing, etc.

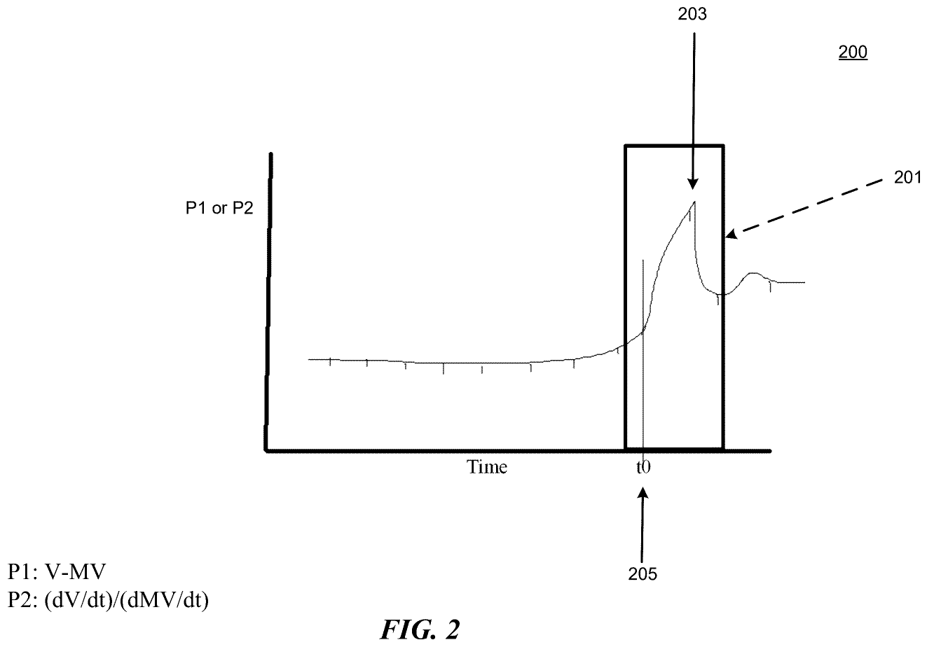

In some embodiments, the combination can be noted as “(P1 or P2),” where “P1” represents the difference between the current voltage value V and the mean voltage value “(V-MV)” and “P2” represents the ratio of the rates “(dV/dt)/(dMV/dt),” as shown in Equations G and H below. In such embodiments, either P1 or P2 can be used for the measurements discussed herein. Embodiments of the foregoing combination are discussed in detail with reference to FIG. 2.

$$P 1 = ( V - MV ) \qquad Equation G$$

$$P 2 = ( dV / dt ) / ( dMV / dt ) \qquad Equation H$$

The data storage module 105 is configured to store measured data (e.g., from the measurement model 101), the calculated value (e.g., from the calculation module 103), verification data (e.g., thresholds/criteria for verification by the verification module 107) and other suitable data for the detection system 100.

The verification module 107 is configured to determine whether there is an abnormal event (such as, a contact break at the battery-cell contact 13) in the battery back 10 based on the calculated value and the verification data. In some embodiments, the verification module 107 can compare the calculated value with a predetermined threshold indicated by the verification data and then identify the abnormal event, if any. For example, the predetermined threshold can be a value fluctuation, a value change pattern, etc. within a predetermined time (e.g., a debounce time for noise removing, such as 100-500 milliseconds). Embodiments of the verification processes performed by the verification module 107 are discussed in detail with reference to FIGS. 2-4.

In some embodiments, without wishing to be bound by theory, the predetermined threshold can be a set of events. For example, a battery-pack contact break can be confirmed (1) when an absolute value of “V-MV” changes by more than “10 mV” within 200 ms for a cell pair, and (2) the absolute value of “V-MV” keeps increasing for 1s or more. In some embodiments, a battery-pack contact break can be confirmed (1) when “d(V/MV)/dt” increases by more than “0.025” per see in a time period such as 200 ms, In some embodiments, other suitable threshold values can be used in various cases.

The communication module 109 is configured to communicate with an external device via a network communication 14 (e.g., based on wired or wireless protocols, such as Wi-Fi, cellular, radio, satellite, Bluetooth, ZigBee, etc.). In some embodiments, the communication module 109 can report the result of the verification processes performed by the verification module 107 to the external device 111. Embodiments of the external device 111 include a server, a computing device, a machine, a vehicle, a network node, a data center, etc.

In some embodiments, the detection system 100 can be implemented in a controller of a machine (e.g., an excavator, a bulldozer, etc.) that includes a battery pack with multiple battery cells therein. In such embodiments, the controller can be integrally form with or be part of a processing unit such as an electronic control unit (ECU) of a vehicle or a machine. In some embodiments, the detection system 100 can be a distributed system (e.g., with the measurement module 101 physically close to the battery pack 10, and the calculation module 103 and/or the verification module 107 are/is on a remote side (e.g., at a server via a network) physically away from the battery pack 10.

FIG. 2 is a schematic diagram illustrating a detection scheme 200 in accordance with embodiments of the present technology. In the illustrated embodiments, the detection scheme 200 utilizes parameter “(P1 or P2)” as its calculated value for identifying an abnormal event (e.g., a contact break of a battery-cell contact) in a battery back. “P1” represents the difference between the current voltage value V and the mean voltage value “(V-MV)” and “P2” represents the ratio of a voltage rate and a mean voltage rate “(dV/dt)/(dMV/dt).” In the illustrated embodiment, the detection scheme 200 monitors the calculated value along time. When a surge of the calculated value (e.g., a sudden increase of value within a determined period of time) is identified (starting from time t0 205 as shown in FIG. 2), the detection scheme 200 can then verify whether the surge can qualify as an abnormal event by comparing the calculated value with a predetermined threshold (e.g., a voltage changing pattern). If the comparison shows a match, the detection scheme 200 can then identify a contact break (CB) 201 and then report the CB 201 to an operator for further actions. In the illustrated embodiments, the CB 201 can be identified according to a peak 203 and the time t0 205. In other embodiments, the CB 201 can be identified by other suitable features and/or characteristics.

The detection scheme 200 at least include that: (1) it is suitable for both charging and discharging scenarios; (2) it provides real-time or near real time prediction/detection (much faster than traditional methods); (3) the scheme 200 can be used to identify a failure even when a system is offline (e.g., parameter “P1 or P2” can be stored in a memory such as a non-volatile memory NVM); and (4) the scheme 200 is suitable for prediction/detection in high transient current scenarios.

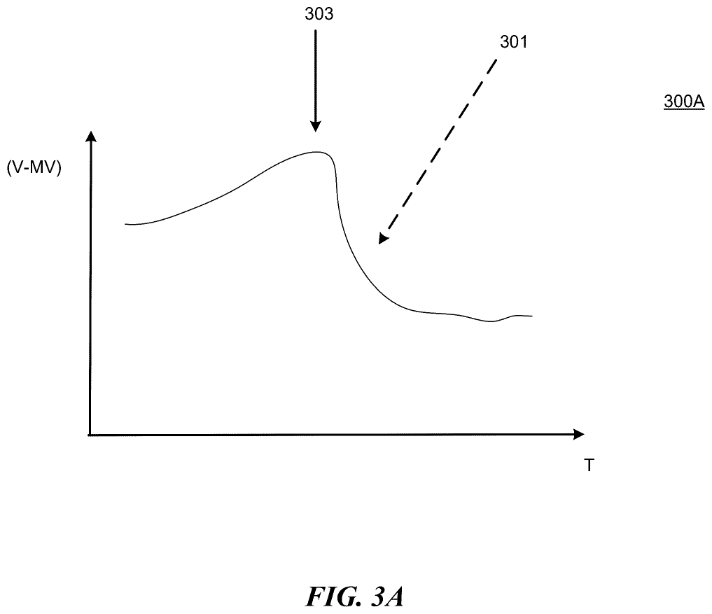

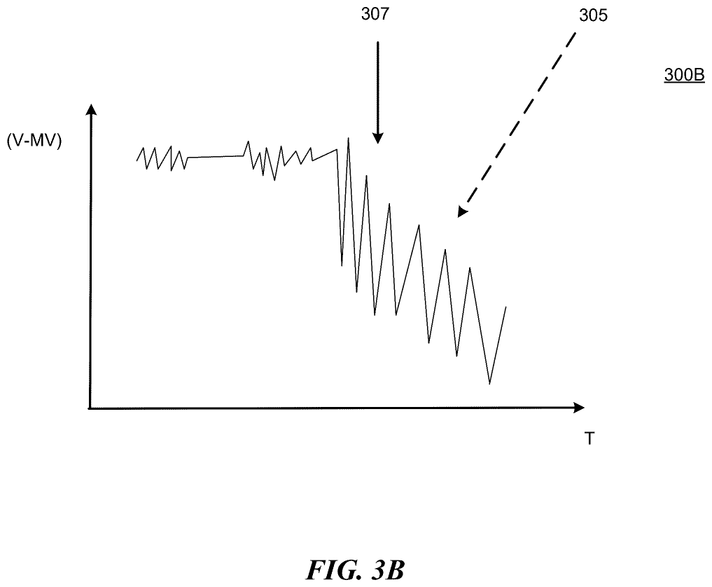

FIG. 3A is a schematic diagram illustrating another detection scheme 300A in accordance with embodiments of the present technology. In the illustrated embodiments, the detection scheme 300A utilizes parameter “(V-MV)” as its calculated value. Parameter “(V-MV)” represents the difference between the current voltage value V and the mean voltage value. In the illustrated embodiment, the detection scheme 300A monitors the calculated value along time. When a drop of the calculated value (e.g., a sudden decrease of value within a determined period of time) is identified, the detection scheme 300A can then verify whether the drop can be qualified as an abnormal event by comparing the calculated value with a predetermined threshold (e.g., a voltage changing pattern). If the comparison shows a match, the detection scheme 300 can then identify a contact break CB 301 and then report the CB 301 to an operator for further actions. In the illustrated embodiments, the CB 301 can be identified according to a peak 303. In other embodiments, the CB 301 can be identified by other suitable features and/or characteristics.

FIG. 3B shows another detection scheme 300B utilizing parameter “(V-MV)” to detect a contract break CB 305. In FIG. 3B, the CB 305 can be identified based on a trend of multiple dropping peaks 307 within a predetermined time period. In other embodiments, the CB 305 can be identified by other suitable features and/or characteristics.

The detection schemes 300A and 300B at least include that: (1) these schemes are suitable for both charging and discharging scenarios; (2) these schemes provide real-time or near real time prediction/detection (much faster than traditional methods); (3) these schemes can be used to identify a failure even when a system is offline (e.g., parameter “(V-MV)” can be stored in a memory such as a non-volatile memory NVM); (4) these schemes are suitable for prediction/detection in high transient current scenarios; and (5) parameter “(V-MV)” is simple and easy to calculate.

FIG. 4A is a schematic diagram illustrating yet another detection scheme 400A in accordance with embodiments of the present technology. In the illustrated embodiments, the detection scheme 400A utilizes parameter “(dV/dt)/(dMV/dt)” as its calculated value. Parameter “(dV/dt)/(dMV/dt)” represents the ratio of a voltage rate “(dV/dt)” and a mean voltage rate “(dMV/dt).” In the illustrated embodiment, the detection scheme 400 monitors the calculated value along time. When a combination of a surge and a drop of the calculated value is identified, the detection scheme 400 can then verify whether the identified combination can be qualified as an abnormal event by comparing the calculated value with a predetermined threshold (e.g., a voltage changing pattern). If the comparison shows a match, the detection scheme 400A can then identify a contact break CB 401 and then report the CB 401 to an operator for further actions. In the illustrated embodiments, the CB 401 can be identified according to a peak 403. In other embodiments, the CB 401 can be identified by other suitable features and/or characteristics.

FIG. 4B shows another detection scheme 400B utilizing parameter “(dV/dt)/(dMV/dt)” to detect a contract break CB 405. In FIG. 4B, the CB 405 can be identified based on multiple peaks. For example, a higher peak 407 following a normal peak 409 can be used to identify the CB 405. In other embodiments, the CB 405 can be identified by other suitable features and/or characteristics.

FIG. 4C shows yet another detection scheme 400C utilizing parameter “d(V/MV)/dt” to detect a contract break CB 411. In FIG. 4C, the CB 411 can be identified based on a surge and a drop of the calculated value. For example, a peak 413 following a drop 415 can be used to identify the CB 411. In other embodiments, the CB 411 can be identified by other suitable features and/or characteristics.

The detection schemes 400A, 400B, and 4000 at least include that: (1) these schemes are suitable for both charging and discharging scenarios; (2) these schemes provide real-time or near real time prediction/detection (much faster than traditional methods); (3) these schemes can be used to identify a failure even when a system is offline (e.g., parameter “(dV/dt)/(dMV/dt)” or “d(V/MV)/dt” can be stored in a memory such as a non-volatile memory NVM); and (4) these schemes are suitable for prediction/detection in high transient current scenarios.

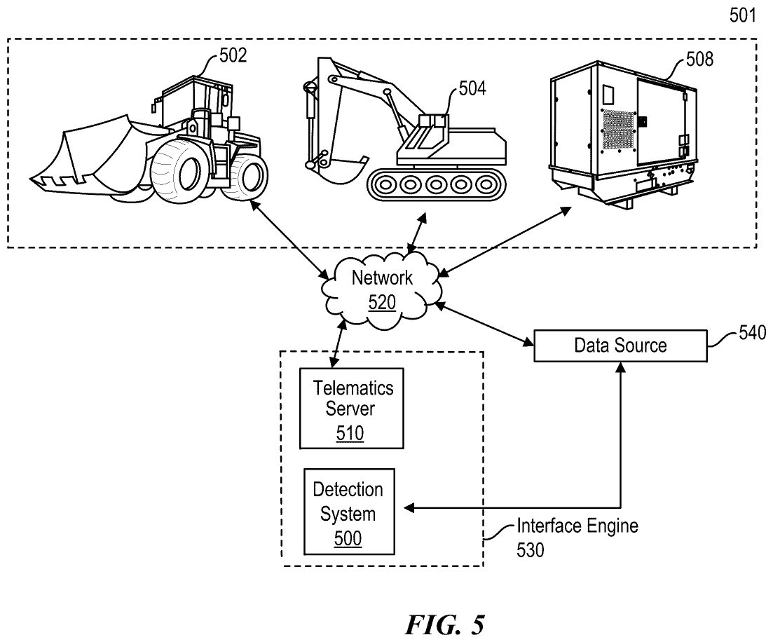

FIG. 5 is a schematic diagram illustrating operations of a detection system 500 in accordance with embodiments of the present technology. The detection system 500 can be a divided system that works with sensors/processors/controllers of multiple machines 501, including, for example, as a dozer 502, an excavator 504, and an energy storage system (ESS) 508. The multiple machines 501 include battery packs with battery cells connected by battery-cell contacts (e.g., the battery-cell contact 13 discussed in FIG. 1). The detection system 500 can communicate with a telematics server 510 for measured data (e.g., current voltage values of the battery packs of the multiple machines 501). The telematics server 510 can communicate with the multiple machines 501 via a network 520. The detection system 500 and the telematics server 510 can be controlled or accessed via an integral interface engine 530. In some embodiments, the integral interface engine 530 enables an operator to control, monitor, and interact with the detection system 500 and the telematics server 510 at the same time. The detection system 500 can communicate with a data source 540, which can be configured to store data associated with the detection system 500 (e.g., measured voltage values of the battery packs of the multiple machines 501, calculated values based on the measured voltage value, verification data such as thresholds/criteria for identify qualified events, etc.).

In various embodiments, the multiple machines 501 can include various mobile machinery items, such as earth moving machinery, mobile construction machinery and so forth, which perform various tasks, such as excavation, loading, transportation, drilling, spreading, compacting, and/or trenching of earth, rock and other materials and can be deployed for work on roads, in quarries, in mines and so forth. In some embodiments, the multiple machines 501 can include loaders (swing loaders, skid-steer loaders, backhoe loaders, and so forth), trenchers, dumpers, scrapers, graders, landfill compactors, rollers, pipelayers, drills, tool carriers, drainage pipe layers, ploughs, mixers (e.g., concrete mixers) and so forth. The multiple machines 501 can be individual machines or combinations of devices (e.g., combinations of base machines and equipment or attachments, such as augers, buckets, blades, tillers, forks, rakes, trenchers, shears, compactors, and so forth) where the combinations can be identified by a product identification number (PIN), machine serial number, or any suitable identifier.

In some embodiments, the multiple machines 501 can include a set of sensors and a set of controllers so as to generate and report various items of information. The sensors can be configured to enable monitoring a variety of operating conditions, including real-time operating conditions of the multiple machines 501 and real-time operating conditions for asset components (e.g., engine, attachments, surroundings, operating environment and so forth). The sensors can collect operating data, which is transmitted by the controllers, via the network 520, to the telematics server 510.

The network 520 can operate according to one or more wired or wireless protocols, such as Wi-Fi, cellular, radio, satellite, Bluetooth, ZigBee, etc. To enable transmission of data and traffic management, the network 520 can include connectivity equipment, such as modems, Bluetooth transceivers, Bluetooth beacons, RFID transceivers, NFC transmitters, and the like. In some implementations, the network 520 can include a controller area network (CAN).

In some embodiments, the sensors can provide analog readings and/or digital readings. The information provided by the sensors can be used to perform on-board and/or remote diagnostics of the multiple machines 501 and can relate to various operating parameters (including the current voltage value of a battery pack) of the multiple machines 501.

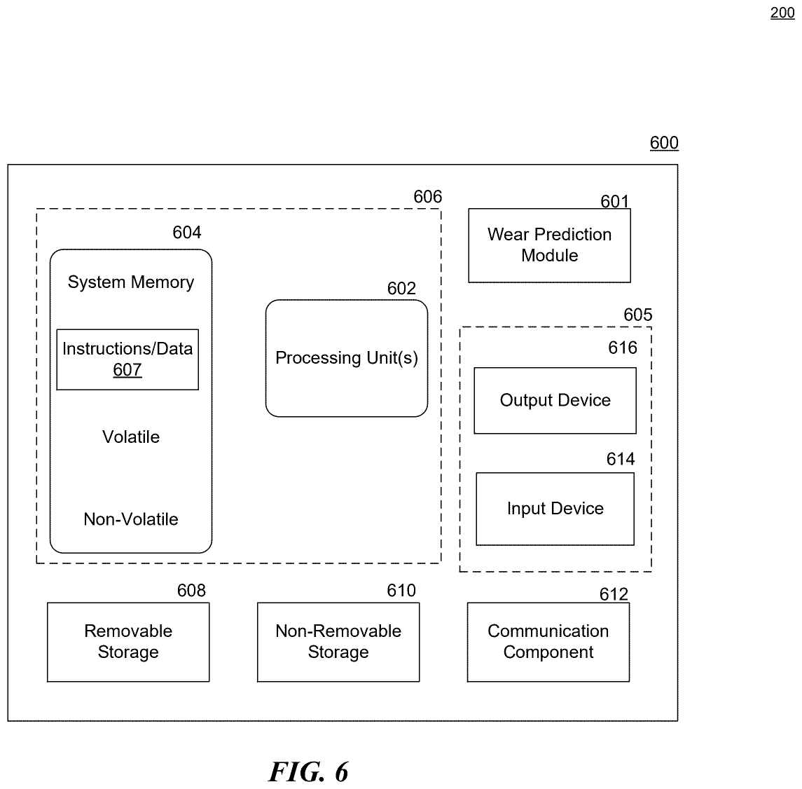

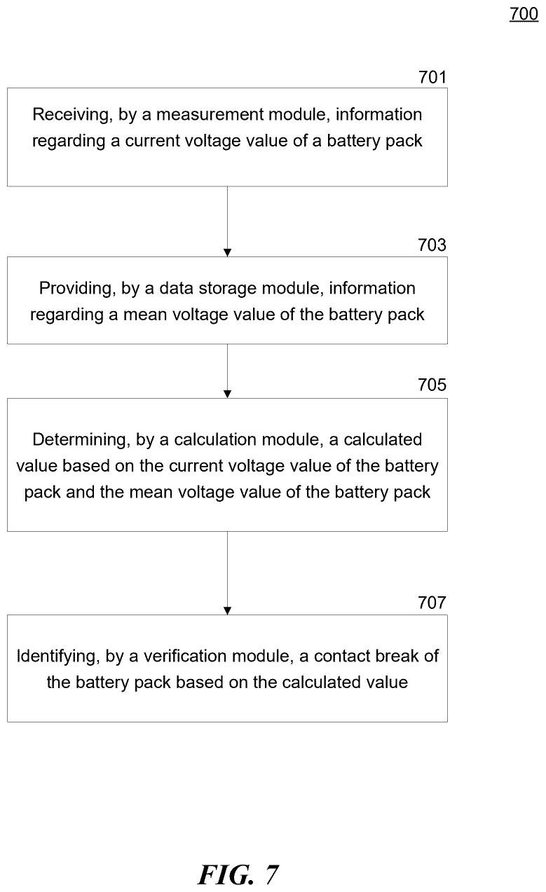

FIG. 6 is a schematic diagram illustrating components in a computing device 600 in accordance with embodiments of the present technology. The computing device 600 can be used to implement methods (e.g., FIG. 7) discussed herein. The computing device 600 can be used to perform the processes/operations discussed in FIGS. 1-5. Note the computing device 600 is only an example of a suitable computing device and is not intended to suggest any limitation as to the scope of use or functionality. Other well-known computing systems, environments, and/or configurations that may be suitable for use include, but are not limited to, personal computers (PCs), server computers, hand-held or laptop devices, multiprocessor systems, microprocessor-based systems, programmable consumer electronics such as smart phones, network PCs, minicomputers, mainframe computers, distributed computing environments that include any of the above systems or devices, and the like.

In its most basic configuration, the computing device 600 includes at least one processing unit 602 and a memory 604. Depending on the exact configuration and the type of computing device, the memory 604 may be volatile (such as a random-access memory or RAM), non-volatile (such as a read-only memory or ROM, a flash memory, etc.), or some combination of the two. This basic configuration is illustrated in FIG. 6 by dashed line 606. Further, the computing device 600 may also include storage devices (a removable storage 608 and/or a non-removable storage 610) including, but not limited to, magnetic or optical disks or tape. Similarly, the computing device 600 can have an input device 614 such as keyboard, mouse, pen, voice input, etc. and/or an output device 616 such as a display, speakers, printer, etc. Also included in the computing device 600 can be one or more communication components 612, such as components for connecting via a local area network (LAN), a wide area network (WAN), cellular telecommunication (e.g. 3G, 4G, 5G, etc.), point to point, any other suitable interface, etc.

The computing device 600 can include a wear prediction module 601 configured to implement methods for operating the machines based on one or more sets of parameters corresponding to components of the machines in various situations and scenarios. For example, the wear prediction module 601 can be configured to implement the wear prediction process discussed herein. In some embodiments, the wear prediction module 601 can be in form of tangibly stored instructions, software, firmware, as well as a tangible device. In some embodiments, the output device 616 and the input device 614 can be implemented as the integrated user interface 605. The integrated user interface 605 is configured to visually present information associated with inputs and outputs of the machines.

The computing device 600 includes at least some form of computer readable media. The computer readable media can be any available media that can be accessed by the processing unit 602. By way of example, the computer readable media can include computer storage media and communication media. The computer storage media can include volatile and nonvolatile, removable and non-removable media (e.g., removable storage 608 and non-removable storage 610) implemented in any method or technology for storage of information such as computer readable instructions, data structures, program modules or other data. The computer storage media can include, an RAM, an ROM, an electrically erasable programmable read-only memory (EEPROM), a flash memory or other suitable memory, a CD-ROM, digital versatile disks (DVD) or other optical storage, magnetic cassettes, magnetic tape, magnetic disk storage or other magnetic storage devices, or any other tangible medium which can be used to store the desired information.

The computing device 600 includes communication media or component 612, including non-transitory computer readable instructions 607, data structures, program modules, or other data. The computer readable instructions 607 can be transported in a modulated data signal such as a carrier wave or other transport mechanism and includes any information delivery media. The term “modulated data signal” means a signal that has one or more of its characteristics set or changed in such a manner as to encode information in the signal. By way of example, and not limitation, the communication media can include wired media such as a wired network or direct-wired connection, and wireless media such as acoustic, radio frequency (RF), infrared and other wireless media. Combinations of any of the above should also be included within the scope of the computer readable media.

The computing device 600 may be a single computer operating in a networked environment using logical connections to one or more remote computers. The remote computer may be a personal computer, a server, a router, a network PC, a peer device or other common network node, and typically includes many or all of the elements described above as well as others not so mentioned. The logical connections can include any method supported by available communications media. Such networking environments are commonplace in offices, enterprise-wide computer networks, intranets and the Internet.

FIG. 7 is a flow diagram showing a method 700 in accordance with embodiments of the present technology. The method 700 can be implemented by a detection system (e.g., the detection system 100 or 500) discussed herein. The method 700 starts at block 701 by receiving, by a measurement module, information regarding a current voltage value of a battery pack. In some embodiments, the battery pack includes at least two battery cells arranged in parallel.

At block 703, the method 700 continues by providing, by a data storage module, information regarding a mean voltage value of the battery pack. At block 705, the method 700 continues by determining, by a calculation module, a calculated value based on the current voltage value of the battery pack and the mean voltage value of the battery pack. At block 707, method 700 continues by identifying, by a verification module, a contact break of the battery pack based on the calculated value. In some embodiments, the contact break occurs at a battery-cell contact between the at least two battery cells.

In some embodiments, the calculated value incudes a difference between the current voltage value of the battery pack and the mean voltage value of the battery pack (e.g., “(V-MV)”). Embodiments the foregoing features are discussed in detail with reference to FIG. 3.

In some embodiments, the calculated value incudes a rate of change of the current voltage value of the battery pack (e.g., “dV/dt”). In some embodiments, the calculated value incudes a rate of change of the mean voltage value of the battery pack (e.g., dMV/dt). In some embodiments, the calculated value incudes a first rate of change of the individual cell pair voltage value of the battery pack (e.g., dV/dt) and a second rate of change of the mean voltage value of the battery pack (dMV/dt). In some embodiments, the calculated value incudes a ratio determined based on the first rate of change and the second rate of change “(dV/dt)/(dMV/dt).” In some embodiments, the calculated value can include a ratio determined based on the current voltage value “V” and the mean voltage value “MV.” In such embodiments the ratio can be “V/MV,” and the calculated value can be “d(V/MV)/dt.” Embodiments the foregoing features are discussed in detail with reference to FIGS. 4A-4C.

In some embodiments, the calculated value can include a difference between the current voltage value of the battery pack and the mean voltage value of the battery pack (V-MV). The calculated value can also include a first rate of change of the individual cell pair voltage value of the battery pack (dV/dt) and a second rate of change of the mean voltage value of the battery pack (dMV/dt).

In some embodiments, the calculated value can include a difference between the current voltage value of the battery pack and the mean voltage value of the battery pack (V-MV). The calculated value can also include a first rate of change of the individual cell pair voltage value of the battery pack (dV/dt) and a second rate of change of the mean voltage value of the battery pack (dMV/dt). The calculated value can also include a ratio determined based on the first rate of change and the second rate of change (e.g., P1 or P2; P1 represents “(V-MV)” and P2 represents “(dV/dt)/(dMV/dt)”). Embodiments the foregoing features are discussed in detail with reference to FIG. 2.

In some embodiments, the contact break can be identified based on a predefined time. In some implementations, the predefined time can be a debounce time (e.g., for noise removing), such as 10 to 500 milliseconds. In some embodiments, the predefined time can vary due to numerous factors such as types of battery pack, types of battery cell, types of battery-cell contacts, etc. The present technology provides a solution that eliminates or significantly reduces the chance of false alarms by enabling an operator to capture sudden changes of the parameters discussed herein, with the consideration of a debounce time.

### INDUSTRIAL APPLICABILITY

The systems and methods described herein can effectively communicate with and manage battery packs of multiple nodes (e.g., a machine, a, devices, a, vehicle, etc.) of a network. The methods enable an operator, experienced or inexperienced, to effectively manage battery packs and identify abnormal events (e.g., contract break CB) without complex data computation/processing so as to reduce interrupting the ongoing tasks of the multiple nodes. The present systems and methods can also be implemented to efficiently manage operations of multiple industrial machines/vehicles/devices by effectively monitoring statuses of the battery packs of these multiple industrial machines/vehicles/devices.

The above description and drawings are illustrative and are not to be construed as limiting. Numerous specific details are described to provide a thorough understanding of the disclosure. However, in some instances, well-known details are not described in order to avoid obscuring the description. Further, various modifications may be made without deviating from the scope of the embodiments.

I/We claim:

1. A method, comprising,
receiving, by a measurement module of the system, information regarding a current voltage value of a battery pack;
providing, by a data storage module of the system, information regarding a mean voltage value of the battery pack;
determining, by a calculation module of the system, a calculated value based on the current voltage value of the battery pack and the mean voltage value of the battery pack; and
identifying, by a verification module of the system, a contact break of the battery pack based on the calculated value.

2. The method of claim 1, wherein the battery pack includes at least two battery cells arranged in parallel.

3. The method of claim 2, wherein the contact break occurs at a battery-cell contact between the at least two battery cells.

4. The method of claim 1, wherein the calculated value includes a difference between the current voltage value of the battery pack and the mean voltage value of the battery pack.

5. The method of claim 1, wherein the calculated value includes a rate of change of the current voltage value of the battery pack.

6. The method of claim 1, wherein the calculated value includes a rate of change of the mean voltage value of the battery pack.

7. The method of claim 1, wherein the calculated value includes a first rate of change of the current voltage value of the battery pack and a second rate of change of the mean voltage value of the battery pack.

8. The method of claim 1, wherein the calculated value includes a ratio determined based on the current voltage value of the battery pack and the mean voltage value of the battery pack.

9. The method of claim 1, wherein the calculated value includes a difference between the current voltage value of the battery pack and the mean voltage value of the battery pack, wherein the calculated value incudes a first rate of change of the current voltage value of the battery pack and a second rate of change of the mean voltage value of the battery pack.

10. The method of claim 1, wherein the calculated value includes a difference between the current voltage value of the battery pack and the mean voltage value of the battery pack, wherein the calculated value incudes a first rate of change of the current voltage value of the battery pack and a second rate of change of the mean voltage value of the battery pack, wherein the calculated value incudes a ratio determined based on the first rate of change and the second rate of change.

11. The method of claim 1, wherein the contact break is identified based on a predefined threshold associated with the mean voltage value of the battery pack.

12. The method of claim 1, wherein the contact break is identified based on a predefined threshold associated with the current voltage value of the battery pack.

13. The method of claim 1, wherein the contact break is identified based on a predefined debounce time.

14. A system, comprising,
a memory, and
a controller coupled to the memory and configured to:
receive, by a measurement module of the controller, information regarding a current voltage value of a battery pack;
provide, by a data storage module of the controller, information regarding a mean voltage value of the battery pack;
determine, by a calculation module of the controller, a calculated value based on the current voltage value of the battery pack and the mean voltage value of the battery pack; and
identify, by a verification module of the controller, a contact break of the battery pack based on the calculated value.

15. The system of claim 14, wherein the battery pack includes at least two battery cells arranged in parallel, and wherein the contact break occurs at a battery-cell contact between the at least two battery cells.

16. The system of claim 14, wherein the calculated value incudes a difference between the current voltage value of the battery pack and the mean voltage value of the battery pack.

17. The system of claim 14, wherein the calculated value incudes a first rate of change of the current voltage value of the battery pack and a second rate of change of the mean voltage value of the battery pack.

18. The system of claim 17, wherein the calculated value incudes a ratio determined based on the first rate of change and the second rate of change.

19. A system, comprising,
at least one hardware processor; and
at least one non-transitory memory storing instructions, which, when executed by the at least one hardware processor, cause the system to:
receive information regarding a current voltage value of a battery pack;
provide, by a data storage module of the system, information regarding a mean voltage value of the battery pack;
determine, by a calculation module of the system, a calculated value based on the current voltage value of the battery pack and the mean voltage value of the battery pack; and
identify, by a verification module of the system, a contact break of the battery pack based on the calculated value.

20. The system of claim 19, wherein the calculated value incudes a difference between the current voltage value of the battery pack and the mean voltage value of the battery pack, wherein the calculated value further incudes a first rate of change of the current voltage value of the battery pack and a second rate of change of the mean voltage value of the battery pack.
